(19) United States
(12) Patent Application Publication
(10) Pub. No.: US 2016/0305239 A1
(43) Pub. Date: Oct. 20, 2016

(54) DOWNHOLE MONITORING OF FLUIDS USING NUCLEAR MAGNETIC RESONANCE

(71) Applicant: SCHLUMBERGER TECHNOLOGY CORPORATION, Sugar Land, TX (US)

(72) Inventors: Timothy Andrew John Hopper, Subiaco (AU); Yi-Qiao Song, Newton Center, MA (US)

(21) Appl. No.: 15/102,391

(22) PCT Filed: Dec. 8, 2014
(86) PCT No.: PCT/US2014/069029

§ 371 Date: Jun. 7, 2016

Related U.S. Application Data
(60) Provisional application No. 61/913,339, filed on Dec. 8, 2013.

(51) Int. Cl. E21B 49/08; G01R 33/385; G01V 3/32

(52) U.S. Cl. CPC E21B 49/08; G01V 3/32; G01R 33/385

(57) ABSTRACT

A downhole logging tool, in an illustrative embodiment, includes an NMR measurement system with surface NMR microcoils located on an outer surface of the downhole logging tool. Each surface NMR microcoil has a central axis and is distributed around the outer surface of the logging tool with the surface NMR microcoil central axis perpendicular to the longitudinal axis of the logging tool. The NMR measurement system may have a central flow line in fluid communication with the drilling fluid. Additional surface NMR microcoils or a flow line microcoil may be disposed circumferentially around the central flow line with the surface NMR microcoil central axis and the flow line NMR microcoil central axis, respectively, perpendicular and parallel to the central flow line longitudinal axis. The NMR measurement system may include a bypass flow line in fluid communication with fluid in the wellbore annulus and/or the drill pipe.

### CROSS REFERENCE TO RELATED APPLICATIONS

This Application claims the benefit to and priority of U.S. Provisional Application No. 61/913,339, filed on Dec. 8, 2013, which is hereby incorporated by reference in its entirety.

### BACKGROUND

1. Technical Field

Embodiments of the present disclosure relate generally downhole fluid analysis using nuclear magnetic resonance.

2. Background Information

This section is intended to introduce the reader to various aspects of art that may be related to various aspects of the subject matter described and/or claimed below. This discussion is believed to be helpful in providing the reader with background information to facilitate a better understanding of the various aspects of the present disclosure. Accordingly, it should be understood that these statements are to be read in this light, not as admissions of prior art.

Logging tools have long been used in wellbores to make, for example, formation evaluation measurements to infer properties of the formations surrounding the borehole and the fluids in the formations. Common logging tools include electromagnetic tools, nuclear tools, acoustic tools, and nuclear magnetic resonance (NMR) tools, though various other types of tools for evaluating formation properties are also available.

Early logging tools were run into a wellbore on a wireline cable after the wellbore had been drilled. Modern versions of such wireline tools are still used extensively. However, as the demand for information while drilling a borehole continued to increase, measurement-while-drilling (MWD) tools and logging-while-drilling (LWD) tools have since been developed. MWD tools typically provide drilling parameter information such as weight on the bit, torque, temperature, pressure, direction, and inclination. LWD tools typically provide formation evaluation measurements such as resistivity, porosity, NMR distributions, and so forth. MWD and LWD tools often have characteristics common to wireline tools (e.g., transmitting and receiving antennas, sensors, etc.), but MWD and LWD tools are designed and constructed to endure and operate in the harsh environment of drilling.

NMR tools used for well-logging or downhole fluid characterization measure the response of nuclear spins in formation fluids to applied magnetic fields. Downhole NMR tools typically include a permanent magnet that produces a static magnetic field at a desired test location (e.g., where the fluid is located). The static magnetic field produces a magnetization in the fluid that is aligned along the direction of the static field. The magnitude of the induced magnetization is proportional to the magnitude of the static field. A transmitter antenna produces a time-dependent radio frequency magnetic field that has a component perpendicular to the direction of the static field. The NMR resonance condition is satisfied when the radio frequency is equal to the Larmor frequency, which is proportional to the magnitude of the static magnetic field. The radio frequency magnetic field produces a torque on the magnetization vector that causes it to rotate about the axis of the applied radio frequency field, and the rotation results in the magnetization vector developing a component perpendicular to the direction of the static magnetic field. This causes the magnetization vector to precess around the static field at the Larmor frequency. At resonance between the Larmor and transmitter frequencies, the magnetization is tipped to the transverse plane (i.e., a plane normal to static magnetic field vector). A series of radio frequency pulses are applied to generate spin echoes that are measured with the antenna.

NMR measurements of oil properties have been used to aid in reservoir fluid characterization since the early 1950s. A detailed knowledge of fluid composition is useful for successful management of oilfield reservoirs. For example, oil composition largely determines the pressure-volume-temperature (PVT) behavior of the reservoir fluid, and the PVT behavior may influence reservoir management decisions. NMR measurements may be used to estimate, among other things, viscosity, T1 relaxation times, T2 relaxation times, diffusion, molecular chain length, chemical structure, emulsion, waxing, and phase transition. Viscosity, for example, may be used as a “fingerprint” to infer other reservoir properties, such as compartmentalization. “Compartmentalization” refers to the geological segmentation of once continuous reservoirs into isolated compartments. Reservoirs that have become compartmentalized may require different approaches to interpretation and production than continuous reservoirs. As a further example, during production there may be “heavy compounds” such as asphaltenes that drop out of solution or waxing problems that may cause loss of production. Measuring fluid properties under downhole conditions may be useful since many properties depend on temperature and pressure. Further, it has been found that some samples may undergo irreversible changes as they are extracted from the formation and transferred to a surface laboratory.

In some NMR systems, one or more very small coils having multiple detectors may be employed. Each of the NMR detection sites may have a fluid router associated with it to direct fluid samples. These coils may have a diameter ranging from between approximately 100 microns to a few millimeters and are often referred to as “microcoils.” The microcoils may be arranged to accommodate a series flow or a parallel flow configuration and may be located so as to experience different static (B0) magnetic field strengths and/or gradient field strengths. Microcoils for use in NMR spectroscopy may be operated at relatively high frequencies. For example, microfluidic NMR has been described in which the hardware used achieves an increase in the signal-to-noise ratio (SNR) and acquires a 1.3 Hz spectral width at 60 MHz. Microcoils operating at such high frequencies may be tuned with a tuning circuit. At lower frequencies, the tuning circuit may be modified accordingly. For example, a fixed inductor may be incorporated into the resonant tuning (LC) circuit to reduce the capacitance. While there are numerous microcoil applications made for high field NMR systems that are operated in static laboratory situations, the use of microcoils for oil field applications such as logging, well testing, and drilling and measurement is largely unexplored.

### SUMMARY

A summary of certain embodiments disclosed herein is set forth below. It should be understood that these aspects are presented merely to provide the reader with a brief summary of certain embodiments and that these aspects are not intended to limit the scope of this disclosure. Indeed, this disclosure may encompass a variety of aspects that may not be set forth in this section.

In one illustrative embodiment, an apparatus includes a downhole logging tool having a longitudinal axis. The downhole logging tool includes a nuclear magnetic resonance (NMR) measurement system that has one or more surface NMR microcoils disposed on or near an outer surface of the downhole logging tool.

In another illustrative embodiment, a method includes providing a downhole logging tool having a longitudinal axis and including a nuclear magnetic resonance (NMR) measurement system that has one or more surface NMR microcoils disposed on or near an outer surface of the downhole logging tool. The method further includes disposing the downhole logging tool in a wellbore having fluids therein, obtaining NMR measurements on fluids proximate to the one or more surface NMR microcoils, and inferring a characteristic of the proximate fluids based on the NMR measurements.

It is understood that the brief summary presented above is intended to familiarize the reader with certain aspects and contexts of embodiments of the present disclosure without limitation to the claimed subject matter.

### BRIEF DESCRIPTION OF DRAWINGS

The present disclosure is better understood from the following detailed description when read with the accompanying figures. It is emphasized that, in accordance with standard practice in the industry, various features are not necessarily drawn to scale. In fact, the dimensions of various features may be arbitrarily increased or recued for clarify of discussion.

FIG. 1 is a diagram of a wellsite system that may be used for implementation of an example embodiment;

FIG. 2 is an example of a nuclear magnetic resonance (NMR) measurement device that may be used in downhole applications;

FIG. 3 is a schematic drawing showing an embodiment of an LWD NMR tool that includes NMR microcoils in accordance with aspects of the present disclosure;

FIG. 4 is a schematic drawing showing another embodiment of an LWD NMR tool that includes NMR microcoils in accordance with aspects of the present disclosure;

FIG. 5 is a schematic drawing showing another embodiment of an LWD NMR tool that includes NMR microcoils in accordance with aspects of the present disclosure;

FIG. 6 is a schematic drawing showing another embodiment of an LWD NMR tool that includes NMR microcoils in accordance with aspects of the present disclosure;

FIG. 7 is a schematic drawing showing another embodiment of an LWD NMR tool that includes NMR microcoils in accordance with aspects of the present disclosure;

FIG. 8 is an example embodiment of a magnet configuration suitable for use with an LWD NMR tool in accordance with aspects of the present disclosure;

FIG. 9 is a flowchart showing an example method for acquiring downhole NMR measurements on downhole fluids using NMR microcoils in accordance with aspects of the present disclosure;

FIG. 10 is a flowchart showing another example method for acquiring downhole NMR measurements on downhole fluids using NMR microcoils in accordance with aspects of the present disclosure;

FIG. 11 is a flowchart showing another example method for acquiring downhole NMR measurements on downhole fluids using NMR microcoils in accordance with aspects of the present disclosure; and

FIG. 12 is a flowchart showing another example method for acquiring downhole NMR measurements on downhole fluids using NMR microcoils in accordance with aspects of the present disclosure.

### DETAILED DESCRIPTION

One or more specific embodiments of the present disclosure are described below. These embodiments are merely examples of the presently disclosed techniques. Additionally, in an effort to provide a concise description of these embodiments, all features of an actual implementation may not be described in the specification. It should be appreciated that in the development of any such implementation, as in any engineering or design project, numerous implementation-specific decisions are made to achieve the developers' specific goals, such as compliance with system-related and business-related constraints, which may vary from one implementation to another. Moreover, it should be appreciated that such development efforts might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The embodiments discussed below are intended to be examples that are illustrative in nature and should not be construed to mean that the specific embodiments described herein are necessarily preferential in nature. Additionally, it should be understood that references to “one embodiment” or “an embodiment” within the present disclosure are not to be interpreted as excluding the existence of additional embodiments that also incorporate the recited features.

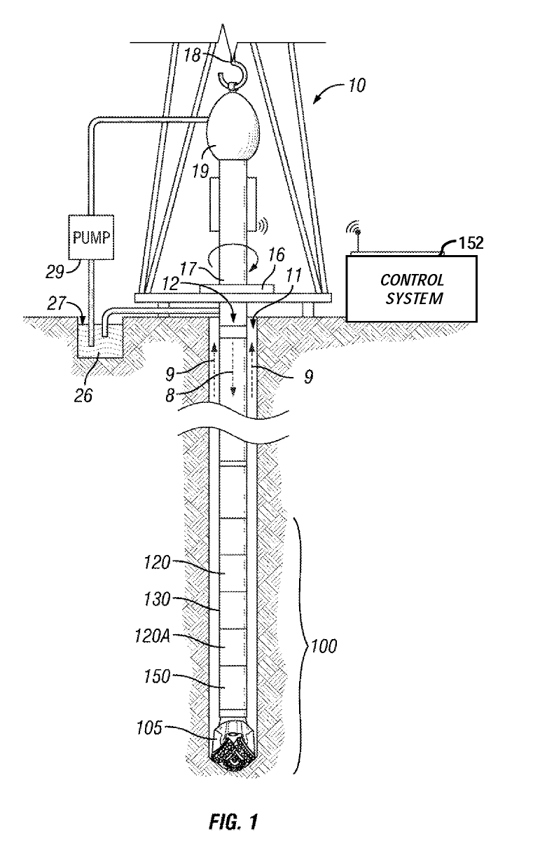

FIG. 1 represents a simplified view of a well site system in which various embodiments can be employed. The well site system depicted in FIG. 1 can be deployed in either onshore or offshore applications. In this type of system, a borehole 11 is formed in subsurface formations by rotary drilling in a manner that is well known to those skilled in the art. Some embodiments can also use directional drilling.

A drill string 12 is suspended within the borehole 11 and has a bottom hole assembly (BHA) 100 which includes a drill bit 105 at its lower end. The surface system includes a platform and derrick assembly 10 positioned over the borehole 11, with the assembly 10 including a rotary table 16, kelly 17, hook 18 and rotary swivel 19. In a drilling operation, the drill string 12 is rotated by the rotary table 16 (energized by means not shown), which engages the kelly 17 at the upper end of the drill string. The drill string 12 is suspended from a hook 18, attached to a traveling block (also not shown), through the kelly 17 and a rotary swivel 19 which permits rotation of the drill string 12 relative to the hook 18. A top drive system could be used in other embodiments.

Drilling fluid or mud 26 may be stored in a pit 27 formed at the well site. A pump 29 delivers the drilling fluid 26 to the interior of the drill string 12 via a port in the swivel 19, which causes the drilling fluid 26 to flow downwardly through the drill string 12, as indicated by the directional arrow 8 in FIG. 1. The drilling fluid exits the drill string 12 via ports in the drill bit 105, and then circulates upwardly through the annulus region between the outside of the drill string 12 and the wall of the borehole, as indicated by the directional arrows 9. In this known manner, the drilling fluid lubricates the drill bit 105 and carries formation cuttings up to the surface as it is returned to the pit 27 for recirculation.

The drill string 12 includes a BHA 100. In the illustrated embodiment, the BHA 100 is shown as having one MWD module 130 and multiple LWD modules 120 (with reference number 120A depicting a second LWD module 120). As used herein, the term “module” as applied to MWD and LWD devices is understood to mean either a single tool or a suite of multiple tools contained in a single modular device. Additionally, the BHA 100 includes a rotary steerable system (RSS) and motor 150 and a drill bit 105.

The LWD modules 120 may be housed in a drill collar and can include one or more types of logging tools. The LWD modules 120 may include capabilities for measuring, processing, and storing information, as well as for communicating with the surface equipment. By way of example, the LWD module 120 may include a nuclear magnetic resonance (NMR) measurement tool, and may include capabilities for measuring, processing, and storing information, and for communicating with surface equipment.

The MWD module 130 is also housed in a drill collar, and can contain one or more devices for measuring characteristics of the drill string and drill bit. In the present embodiment, the MWD module 130 can include one or more of the following types of measuring devices: a weight-on-bit measuring device, a torque measuring device, a vibration measuring device, a shock measuring device, a stick/slip measuring device, a direction measuring device, and an inclination measuring device (the latter two sometimes being referred to collectively as a D&I package). The MWD tool 130 further includes an apparatus (not shown) for generating electrical power for the downhole system. For instance, power generated by the MWD tool 130 may be used to power the MWD tool 130 and the LWD tool(s) 120. In some embodiments, this apparatus may include a mud turbine generator powered by the flow of the drilling fluid 26. It is understood, however, that other power and/or battery systems may be employed.

The operation of the assembly 10 of FIG. 1 may be controlled using a computer-based control system 152 located at the surface. The control system 152 may include one or more processor-based computing systems. In the present context, a processor may include a microprocessor, programmable logic devices (PLDs), field-gate programmable arrays (FPGAs), application-specific integrated circuits (ASICs), system-on-a-chip processors (SoCs), or any other suitable integrated circuit capable of executing encoded instructions stored, for example, on tangible computer-readable media (e.g., read-only memory, random access memory, a hard drive, optical disk, flash memory, etc.). Such instructions may correspond to, for instance, workflows and the like for carrying out a drilling operation, algorithms and routines for processing data received at the surface from the BHA 100 (e.g., as part of an inversion to obtain one or more desired formation parameters), and so forth.

As will be appreciated by those skilled in the art, NMR well logging tools are typically used to measure the properties of nuclear spins in the formation, such as the longitudinal (or spin-lattice) relaxation time (often referred to as T₁), transverse (or spin-spin) relaxation time (often referred to as T₂), and diffusion coefficient (D). Knowledge of these NMR properties can help aid in determination of basic formation properties such as permeability and porosity, as well as the fluid properties such as fluid type and viscosity.

By way of background, NMR logging tools, i.e., LWD tool 120 of FIG. 1, may use permanent magnets to create a strong static magnetic polarizing field inside the formation. The hydrogen nuclei of water and hydrocarbons are electrically charged spinning protons that create a weak magnetic field, similar to tiny bar magnets. When a strong external magnetic field from the logging tool passes through a formation containing fluids, these spinning protons align themselves like compass needles along the magnetic field. This process, called polarization, increases exponentially with T₁ (longitudinal relaxation time), while the external magnetic field (usually referred to as the B₀ field) is applied.

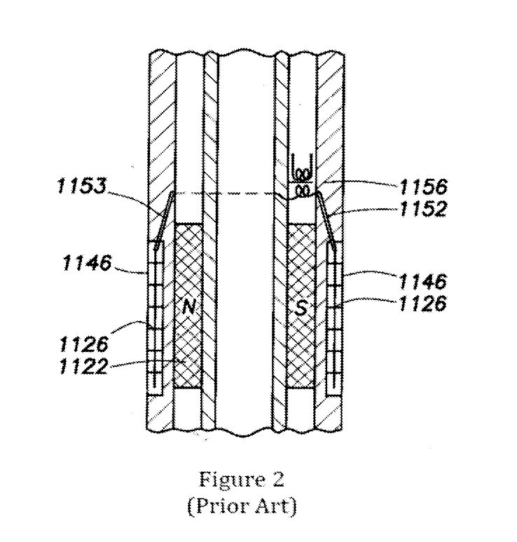

FIG. 2 shows an embodiment of a type of device described in commonly assigned U.S. Pat. No. 5,629,623 for formation evaluation while drilling using pulsed nuclear magnetic resonance (NMR), incorporated herein by reference, it being understood that other types of NMR/LWD tools can also be utilized as the LWD tool 120 or part of an LWD tool suite 120A. As described in the '623 Patent, an embodiment of one configuration of the device includes a modified drill collar having an axial groove or slot that is filled with a ceramic insulator, and contains RF antenna 1126, which is protected by a non-magnetic cover 1146 and produces and receives pulsed RF electromagnetic energy. In the embodiment shown, the conductors of the RF antenna are grounded at one end to the drill collar. At the other end of the drill collar, the conductors are coupled to an RF transformer 1156 via pressure feed-throughs 1152 and 1153. A cylindrical magnet 1122 produces a static magnetic field in the formations. In other embodiments, the RF antenna 1126 can also be arranged so that the drill collar itself produces the oscillating RF magnetic field. In the illustrated example, the oscillating RF magnetic field, which excites nuclei of substances in the formations, is axially symmetric, to facilitate measurements during rotation of the drill string.

Once the desired NMR data is acquired, various mathematical inversion processes can be applied to produce the distribution of measured properties that reflects the anisotropy of formation or formation fluids. For example, the T₂ distribution represents the distribution of pore sizes within the formation, and the area under T₂ curve represents the porosity filled with formation fluids. Interpretation of pore size distribution and logarithmic mean T₂ may be used for calculating various petrophysical parameters, such as permeability and the amount of free/bound fluid.

Indeed, the measurement of diffusion versus relaxation distribution times (D-T2) has proven to be a valuable tool for identifying and quantifying different fluids in a formation. For instance, D-T2 maps from in-situ formation measurements may be obtained using wireline or while-drilling measuring tools. These tools measure the oil in the formation, but may be influenced by the rock wettability and magnetic susceptibility differences. Having an ex-situ NMR measurement at downhole pressure and temperature offers improved fluid characterization accuracy.

One type of analysis that is often used to determine hydrocarbon composition is called Saturates-Aromatics-Resins-Asphaltenes (SARA) analysis. SARA analysis is generally performed in a laboratory setting, but may take considerable time and often is not accurately repeatable. Methodologies of SARA analysis vary between labs and are a cause of concern for accurate fluid characterization and comparison. NMR offers the possibility of providing similar information as SARA analysis at downhole pressure and temperature and in a repeatable manner. Data may be obtained prior to any dropout of asphaltene and/or waxing which may occur when a sample is brought to the surface.

NMR may be used to measure and characterize single phase and multi-phase flow. For instance, NMR provides a method for obtaining complex chemical structures of molecular compositions, as well as bulk relaxation and diffusion measurements. NMR is intrinsically a relatively insensitive technique and successful implementation involves careful consideration of the signal-to-noise ratio (SNR) of the measurement. Traditionally, the SNR is increased by using the highest available magnetic fields and the largest possible sample. However, difficulties with this approach include: (1) generating sufficiently large magnetic fields with the required homogeneity over the whole sample; (2) providing the high power RF amplifiers for generating the required excitation pulses across the whole sample; and (3) in many cases, obtaining a large enough sample. If the sample does not fill the whole sample space, the filling factor decreases and the SNR of the measurement may become too low.

By using microcoils in downhole logging applications, the power requirements for a downhole system may be reduced. Embodiments of systems and methods to monitor downhole fluids using LWD NMR microcoils are disclosed in further detail below. Downhole spectroscopy can be obtained using these NMR microcoil-based techniques. It is understood that the term “microcoil”, as used herein, generally encompasses coils having diameters ranging from approximately 100 microns to a few millimeters, or a few centimeters in some cases.

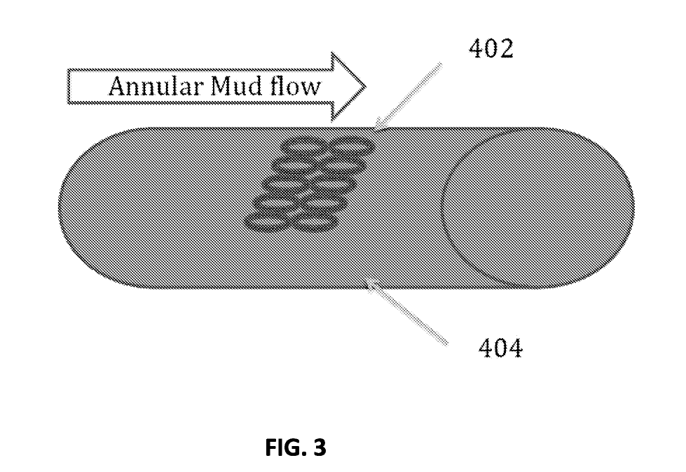

Referring to one illustrative embodiment shown in FIG. 3, NMR microcoils 402 may be mounted on or near the outside surface of a drill collar 404 to measure properties of the mud (drilling fluid) flowing upward (uphole) in the annulus of the borehole (e.g., the space between the drill collar 402 and the wall of the borehole). As used herein, microcoils mounted on or near the outer surface of a downhole tool (e.g., the drill collar of an LWD tool, the sonde casing of a wireline tool, etc.) may be referred to as “surface microcoils,” “surface NMR microcoils,” “surface coils” or the like.

The array of surface NMR microcoil coils 402 depicted in FIG. 3 may be used to measure the mud in the near region of the drill collar 404. The diameter of the surface NMR microcoil 402 affects its depth of investigation from the collar 404 into the mud column. A static magnetic field may be provided by magnets (not shown) embedded in the collar under the NMR microcoils 402 or by magnets (not shown) placed inside the collar 404. Because of the small spatial dimensions of the NMR microcoils 402, a strong, homogeneous, static field can be produced to provide a sufficient signal-to-noise ratio to calculate, for example, the hydrocarbon chain length distribution.

The surface NMR microcoils 402 each have a central axis and may be disposed circumferentially around the outer surface of the LWD tool with the surface NMR microcoil central axis, for any particular surface NMR microcoil 402, being substantially perpendicular to the LWD tool longitudinal axis, substantially parallel to the LWD tool longitudinal axis, or oriented at some angle in between substantially perpendicular and substantially parallel to the LWD tool longitudinal axis. This freedom of orientation of the surface NMR microcoils relative to a relevant passageway is understood to apply to other embodiments described below as well.

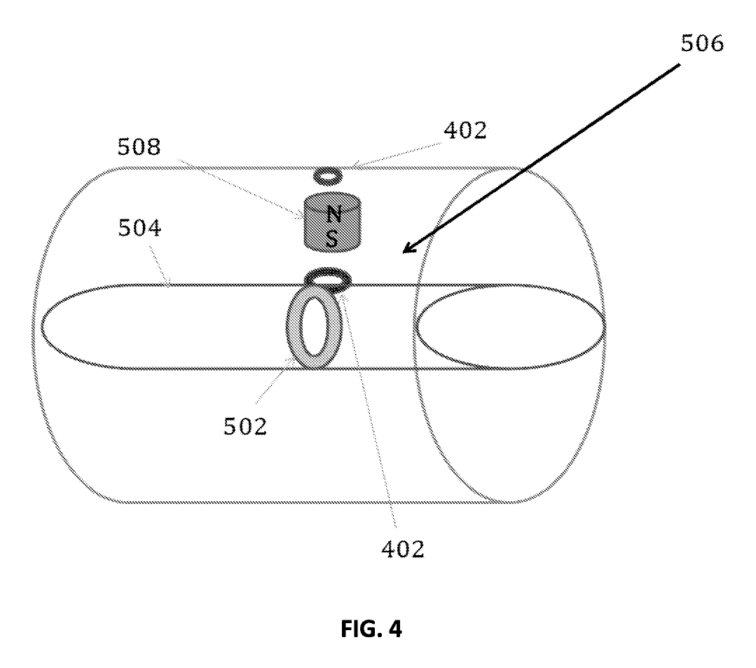

Referring to FIG. 4, another embodiment of a downhole NMR measurement tool that include microcoils is illustrated and includes a combination of surface NMR microcoils 402 and flow line NMR microcoils 502 circumferentially surrounding a flow line 504 can be part of an internal LWD NMR system 506 to make measurements on mud traveling downward (downhole) to the drill bit (e.g., bit 105 of FIG. 1). This may be used in conjunction with surface NMR microcoils 402 mounted on or near the surface of collar 404, which may make measurements on mud traveling upwards (uphole) to the surface. Measurements made on the mud traveling downhole and uphole may provide information regarding hydrocarbons or other gases that were injected into the fluid during the course of drilling. The measurements may include a hydrocarbon chain length distribution based on analysis of various NMR parameters that include, but are not limited to, diffusion and T2 relaxation times. FIG. 4 also shows a representative magnet configuration 508 that is arranged to produce the static magnetic field relative to the surface NMR microcoils 402.

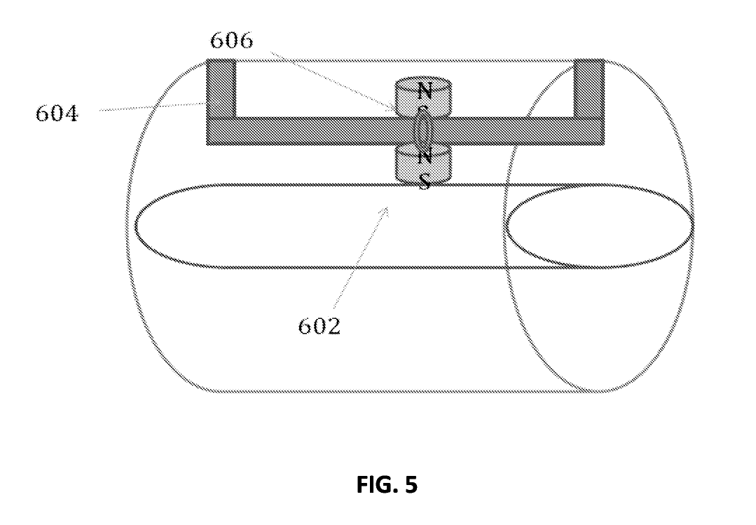

Another embodiment of a downhole microcoil NMR measurement tool is shown in FIG. 5. In this embodiment, the outside annulus mud may be measured by taking a sample from the outside (annulus) mud column and passing it into the tool where an NMR sensor 602 is located. For instance, the fluid to be sampled is drawn into flow line 604 and passed through the downhole NMR sensor 602. NMR sensor 602 may be the embodiment shown, for example, in either FIG. 3 or 4, but is not limited to those. Again, a representative magnet configuration 606 is shown. The NMR sensor 602 may be an NMR microcoil designed to occupy as little space within the drill collar as possible within the LWD tool. Similar to ultrasonic transducers, these small NMR microcoil devices may be embedded nearly anywhere within the tool or on the outside surface thereof. Recent advances in the miniaturization of NMR spectrometers have shown that ultra-compact NMR systems are achievable.

Referring again to FIG. 4, NMR measurements made on “clean” mud on the inside of the drill pipe (e.g., mud traveling downhole from the surface) may be obtained and compared to the NMR measurement of the “contaminated” mud measurement (e.g., mud carrying cuttings traveling up the annulus toward the surface). In this manner, one may discriminate between “virgin” mud and reservoir contaminated mud through the use of NMR fluid typing.

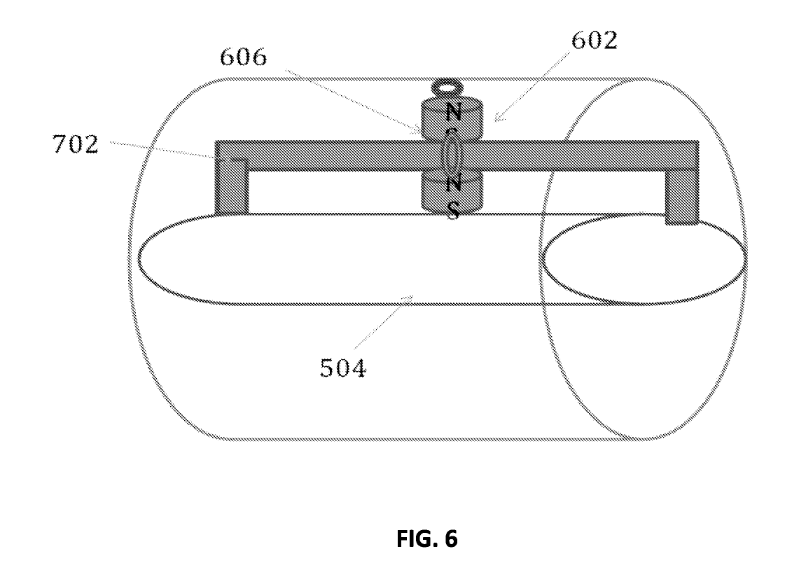

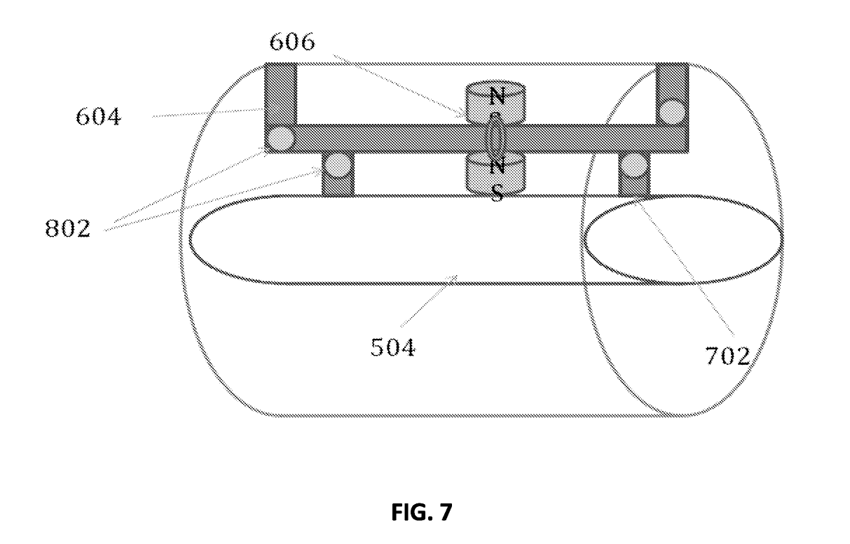

In another embodiment shown in FIG. 6, a bypass flow line 702 from the main tool mud flow line 504 can be directed through an NMR sensor 602. When compared to the embodiment of FIG. 4, this reduces the flow rate and allows for a smaller RF coil to be used, which can further improve the signal-to-noise ratio of the measurement. FIG. 7 shows an embodiment that uses a shared by-pass flow line. In this embodiment, separate entry and exit ports of internal 702 and external 604 bypass flow lines join to a common portion of the bypass flow line. Valves 802 may be included to selectively control fluid flow. For instance, if measurements are to be made on virgin mud, the valves 802 may permit the mud traveling down the mud flow line 504 to enter the bypass flowline while impeding contaminated mud traveling up the annulus from doing the same. Likewise, if measurements are to be made on contaminated mud, the valves 802 may permit the mud traveling up the annulus toward the surface to enter the bypass flowline while impeding virgin mud traveling downhole via the mud flow line 504 from doing the same. As can be appreciated, the valves 802 may be controlled in any suitable manner, including electronically via one or more control signals (e.g., signal from control system 152) or hydraulically.

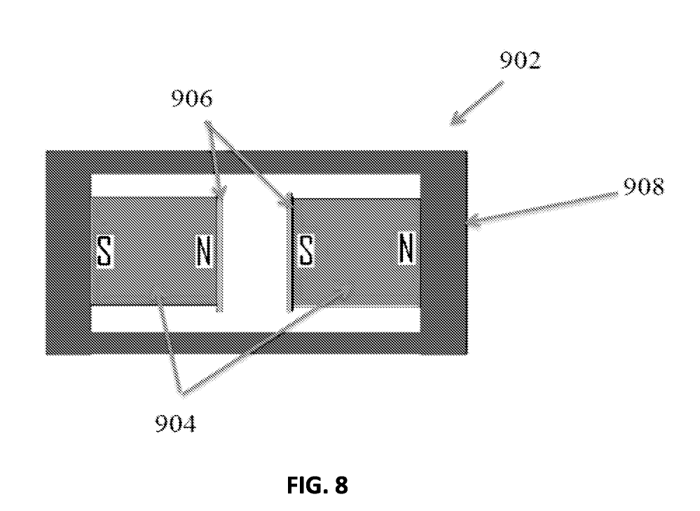

FIG. 8 is a schematic drawing of an example magnet system 902 that may be used in conjunction with NMR microcoil systems, as shown above in FIGS. 3-8. In the illustrated embodiment, the magnet system 902 includes magnets 904, pole pieces 906, and magnetic flux return 908.

As will be appreciated, a number of NMR microcoil sensors can be used at once with varying magnetic field strengths and gradients. These can be used, for example, to speed up fluid identification studies. The use of multiple coils at different locations (e.g., in series or parallel with flow) experiencing different magnetic field strengths can allow one to spatially image the “flow” of a fluid and see how its properties change along a flow path if it is a multi-phase mixture. The use of different gradients may enable diffusion measurements to separate fluid types. Relaxation time (T1, T2) and diffusion measurements on oils and oil/water emulsions using NMR microcoils also permits one to obtain multi-dimensional data (2D, 3D, 4D) in this regard.

Attention is now directed to processing procedures, methods, techniques, and workflows that are in accordance with some embodiments. Some operations in the processing procedures, methods, techniques, and workflows disclosed herein may be combined and/or the order of some operations may be changed. It is recognized that geologic interpretations, sets of assumptions, and/or domain models such as velocity models may be refined in an iterative fashion. This concept is applicable to the processing procedures, methods, techniques, and workflows discussed herein. For instance, such iterative refinements may include use of feedback loops executed on an algorithmic basis, such as at a computing device (e.g., part of control system 152 in FIG. 1), and/or through manual control by a user who may make determinations regarding whether a given step, action, template, or model has become sufficiently accurate for the evaluation of the subsurface geological formation under consideration.

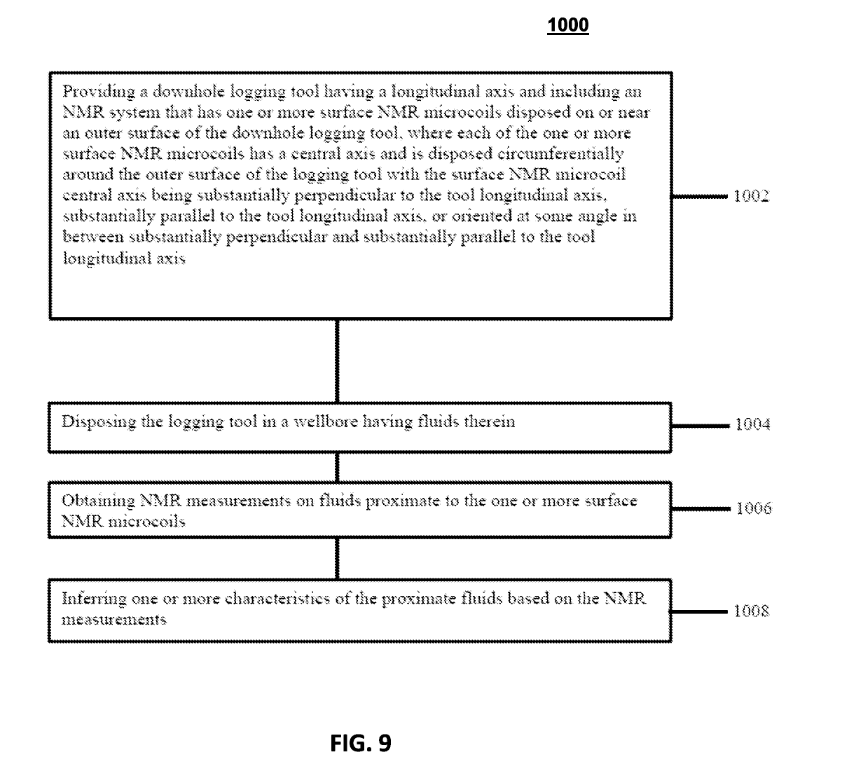

FIG. 9 shows a flowchart illustrating a method embodiment 1000 in accordance with aspects of the present disclosure. The method 1000 includes providing an downhole logging tool having a longitudinal axis and an NMR system that includes one or more NMR microcoils disposed on or near an outer surface of the logging tool, with each of the one or more surface NMR microcoils having a central axis and disposed circumferentially around the outer surface of the logging tool with the surface NMR microcoil central axis being substantially perpendicular to the logging tool longitudinal axis, substantially parallel to the logging tool longitudinal axis, or oriented at some angle in between substantially perpendicular and substantially parallel to the logging tool longitudinal axis (1002). The method 1000 includes disposing the logging tool in a wellbore having fluids therein (1004). NMR measurements are obtained on fluids proximate to the one or more surface NMR microcoils (1006) and one or more characteristics of the proximate fluids are inferred based on the NMR measurements (1008).

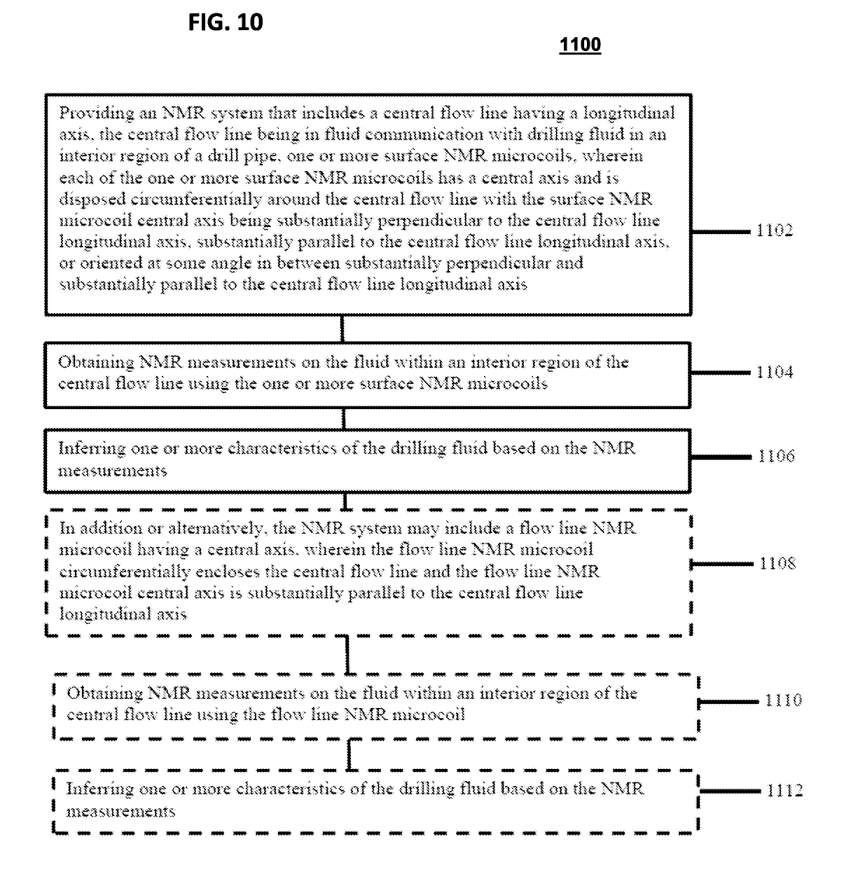

FIG. 10 is a flowchart illustrating another method embodiment 1100 in accordance with aspects of the present disclosure. The method 1100 includes providing an NMR system that includes a central flow line having a longitudinal axis and being in fluid communication with drilling fluid in an interior region of a drill pipe, and one or more additional surface NMR microcoils, wherein each of the one or more additional surface NMR microcoils has a central axis and is disposed circumferentially around the central flow line with the surface NMR microcoil central axis being substantially perpendicular to the central flow line longitudinal axis (1102). The method 1100 includes obtaining NMR measurements on the fluid within an interior region of the central flow line using the one or more additional surface NMR microcoils (1104). One or more characteristics of the drilling fluid are inferred based on the NMR measurements (1106).

As shown in method 1100, 1108-1102 may be performed instead of or in addition to 1102-1106, where the NMR system (from 1102) may include a flow line NMR microcoil having a central axis, wherein the flow line NMR microcoil circumferentially encloses the central flow line and has a central axis is substantially parallel to the central flow line longitudinal axis (1108). NMR measurements are obtained on the fluid within an interior region of the central flow line using the flow line NMR microcoil (1110), and one or more characteristics of the drilling fluid are inferred based on the NMR measurements (1112).

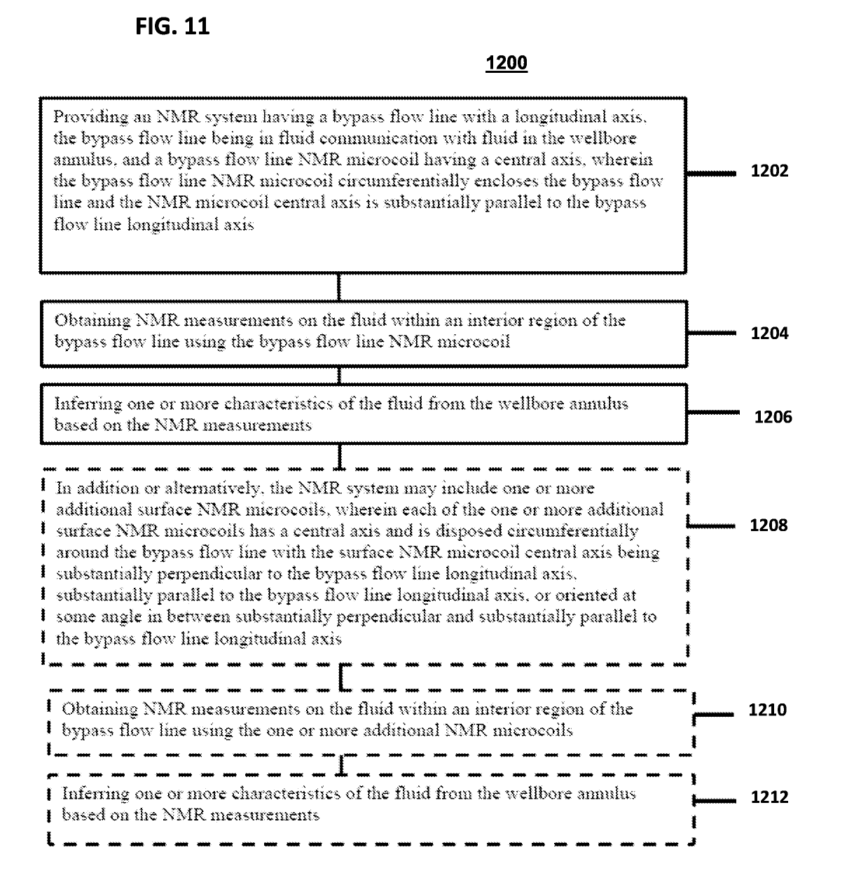

FIG. 11 shows yet another method embodiment 1200 in accordance with aspects of the present disclosure. In accordance with method 1200, an NMR system is provided that includes a bypass flow line having a longitudinal axis and being in fluid communication with fluid in the wellbore annulus and a bypass flow line NMR microcoil having a central axis, wherein the bypass flow line NMR microcoil circumferentially encloses the bypass flow line and the central axis of the flow line NMR microcoil is substantially parallel to the bypass flow line longitudinal axis (1202). NMR measurements are obtained on the fluid within an interior region of the bypass flow line using the bypass flow line NMR microcoil (1204), and one or more characteristics of the fluid in the wellbore annulus is inferred based on the NMR measurements (1206).

As shown in method 1200, 1208-1212 may be performed instead of or in addition to 1202-1206, where the NMR system (from 1202) may include one or more additional surface NMR microcoils, wherein each of the one or more additional surface NMR microcoils has a central axis and is disposed circumferentially around the bypass flow line with the surface NMR microcoil central axis being substantially perpendicular to the bypass flow line longitudinal axis (1208). NMR measurements are obtained on the fluid within an interior region of the bypass flow line using the one or more additional NMR microcoils (1210), and one or more characteristics of of the fluid in the wellbore annulus are inferred based on the NMR measurements (1212).

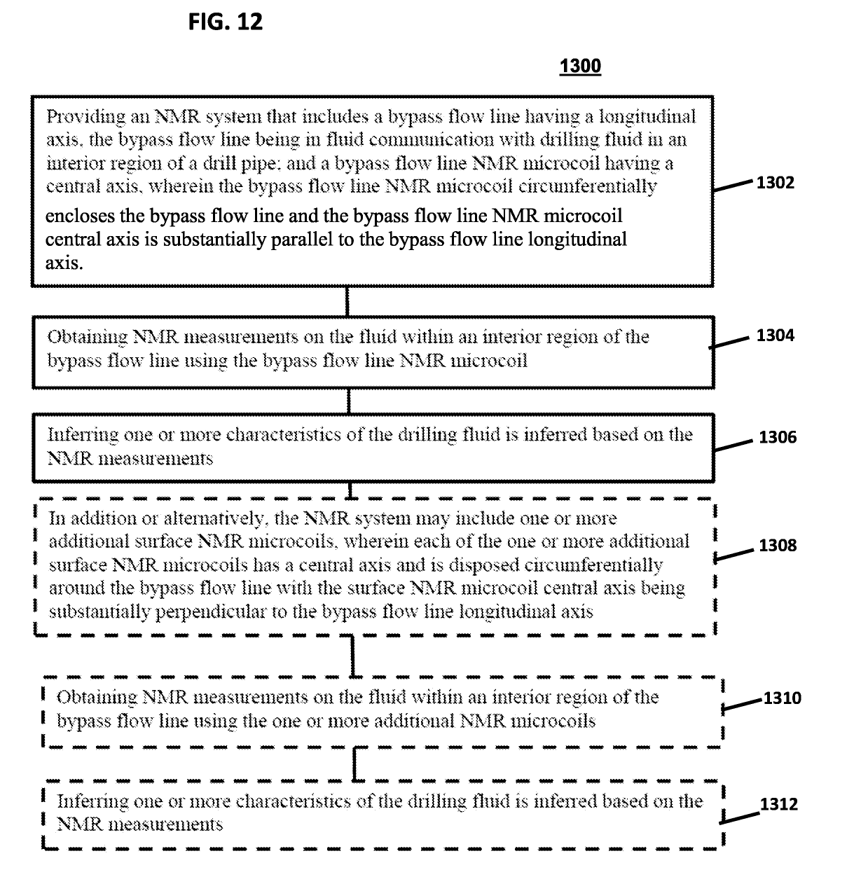

FIG. 12 provides a further method embodiment 1300 in accordance with aspects of the present disclosure. In accordance with method 1300, an NMR system is provided that includes a bypass flow line having a longitudinal axis, the bypass flow line being in fluid communication with drilling fluid in an interior region of a drill pipe, and a bypass flow line NMR microcoil having a central axis, wherein the bypass flow line NMR microcoil circumferentially encloses the bypass flow line with its central axis being substantially parallel to the bypass flow line longitudinal axis (1302). NMR measurements are obtained on the fluid within an interior region of the bypass flow line using the bypass flow line NMR microcoil (1304), and one or more characteristics of the drilling fluid are inferred based on the NMR measurements (1306).

As shown in method 1300 of FIG. 12, 1308-1312 may be performed instead of or in addition to 1302-1306, where the NMR system may include one or more additional surface NMR microcoils, wherein each of the one or more additional surface NMR microcoils has a central axis and is disposed circumferentially around the bypass flow line with the surface NMR microcoil central axis being substantially perpendicular to the bypass flow line longitudinal axis, substantially parallel to the bypass flow line longitudinal axis, or oriented at some angle in between substantially perpendicular and substantially parallel to the bypass flow line longitudinal axis (1308). NMR measurements are obtained on the drilling fluid within an interior region of the bypass flow line using the one or more additional NMR microcoils (1310), and one or more characteristics of the drilling fluid are inferred based on the NMR measurements (1312).

As will be understood, the various techniques described above and relating to the use of NMR microcoils in downhole NMR measurements are provided as example embodiments. Accordingly, it should be understood that the present disclosure should not be construed as being limited to only the examples provided above. Further, it should be appreciated that the NMR measurement techniques disclosed herein may be implemented in any suitable manner, including hardware (suitably configured circuitry), software (e.g., via a computer program including executable code stored on one or more tangible computer readable medium), or via using a combination of both hardware and software elements. Further, it is understood that the NMR measurements acquired using the present described techniques may be processed via a downhole processor (e.g., a processor that is part of an NMR logging tool), with the results sent to the surface by any suitable telemetry technique. Additionally, in other embodiments, NMR measurements may be transmitted uphole via telemetry, and the inversion of such measurements may be performed uphole on a surface computer (e.g., part of control system 152 in FIG. 1).

While the specific embodiments described above have been shown by way of example, it will be appreciated that many modifications and other embodiments will come to the mind of one skilled in the art having the benefit of the teachings presented in the foregoing description and the associated drawings. Accordingly, it is understood that various modifications and embodiments are intended to be included within the scope of the appended claims.

What is claimed is:

1. An apparatus, comprising:
a downhole logging tool having a longitudinal axis, the downhole logging tool comprising an NMR measurement system that comprises one or more surface NMR microcoils disposed on or near an outer surface of the downhole logging tool.

2. The apparatus of claim 1, wherein the one or more surface NMR microcoils each have a central axis and are disposed circumferentially around the outer surface of the downhole logging tool with the surface NMR microcoil central axis, for any particular surface NMR microcoil, being substantially perpendicular to the downhole logging tool longitudinal axis, substantially parallel to the downhole logging tool longitudinal axis, or oriented at some angle in between substantially perpendicular and substantially parallel to the downhole logging tool longitudinal axis.

3. The apparatus of claim 1, wherein the NMR measurement system further comprises:
a central flow line having a longitudinal axis, the central flow line being in fluid communication with drilling fluid in an interior region of a drill pipe; and
one or more additional surface NMR microcoils, wherein each of the one or more additional surface NMR microcoils is disposed near a surface of the central flow line.

4. The apparatus of claim 3, wherein each of the one or more additional surface NMR microcoils has a central axis and is disposed circumferentially around the central flow line with the surface NMR microcoil central axis, for any particular surface NMR microcoil, being substantially perpendicular to the central flow line longitudinal axis, substantially parallel to the central flow line longitudinal axis, or oriented at some angle in between substantially perpendicular and substantially parallel to the central flow line longitudinal axis.

5. The apparatus of claim 1, wherein the NMR measurement system further comprises:
a central flow line having a longitudinal axis, the central flow line being in fluid communication with drilling fluid in an interior region of a drill pipe; and
a flow line NMR microcoil having a central axis, wherein the flow line NMR microcoil circumferentially encloses the central flow line and the flow line NMR microcoil central axis is substantially parallel to the central flow line longitudinal axis.

6. The apparatus of claim 1, wherein the NMR measurement system further comprises:
a bypass flow line having a longitudinal axis, the bypass flow line being in fluid communication with fluid in the wellbore annulus; and
a bypass flow line NMR microcoil having a central axis, wherein the bypass flow line NMR microcoil circumferentially encloses the bypass flow line and the bypass flow line central axis is substantially parallel to the bypass flow line longitudinal axis.

7. The apparatus of claim 1, wherein the NMR measurement system further comprises:
a bypass flow line having a longitudinal axis, the bypass flow line being in fluid communication with fluid in the wellbore annulus; and
one or more additional surface NMR microcoils, wherein each of the one or more additional surface NMR microcoils has a central axis and is disposed circumferentially around the bypass flow line with the surface NMR microcoil central axis being substantially perpendicular to the bypass flow line longitudinal axis, substantially parallel to the bypass flow line longitudinal axis, or oriented at some angle in between substantially perpendicular and substantially parallel to the bypass flow line longitudinal axis.

8. The apparatus of claim 1, wherein the NMR measurement system further comprises:
a bypass flow line having a longitudinal axis, the bypass flow line being in fluid communication with drilling fluid in an interior region of a drill pipe; and
a bypass flow line NMR microcoil having a central axis, wherein the bypass flow line NMR microcoil circumferentially encloses the bypass flow line and the bypass flow line central axis is substantially parallel to the bypass flow line longitudinal axis.

9. The apparatus of claim 1, wherein the NMR measurement system further comprises:
a bypass flow line having a longitudinal axis, the bypass flow line being in fluid communication with drilling fluid in an interior region of a drill pipe; and
one or more additional surface NMR microcoils, wherein each of the one or more additional surface NMR microcoils has a central axis and is disposed circumferentially around the bypass flow line with the surface NMR microcoil central axis being substantially perpendicular to the bypass flow line longitudinal axis, substantially parallel to the bypass flow line longitudinal axis, or oriented at some angle in between substantially perpendicular and substantially parallel to the bypass flow line longitudinal axis.

10. The apparatus of claim 1, wherein the NMR measurement system further comprises:
a bypass flow line having a longitudinal axis, the bypass flow line being selectively in fluid communication with fluid in the wellbore annulus or selectively in fluid communication with drilling fluid in an interior region of a drill pipe; and
a bypass flow line NMR microcoil having a central axis, wherein the bypass flow line NMR microcoil circumferentially encloses the bypass flow line and the bypass flow line central axis is substantially parallel to the bypass flow line longitudinal axis.

11. The apparatus of claim 1, wherein the NMR measurement system further comprises:
a bypass flow line having a longitudinal axis, the bypass flow line being selectively in fluid communication with fluid in the wellbore annulus or selectively in fluid communication with drilling fluid in an interior region of a drill pipe; and
one or more additional surface NMR microcoils, wherein each of the one or more additional surface NMR microcoils has a central axis and is disposed circumferentially around the bypass flow line with the surface NMR microcoil central axis being substantially perpendicular to the bypass flow line longitudinal axis, substantially parallel to the bypass flow line longitudinal axis, or oriented at some angle in between substantially perpendicular and substantially parallel to the bypass flow line longitudinal axis.

12. The apparatus of claim 1, wherein the downhole logging tool comprises a logging-while-drilling tool.

13. A method, comprising:
providing a downhole logging tool having a longitudinal axis, the downhole logging tool comprising an NMR measurement system that comprises one or more surface NMR microcoils disposed on or near an outer surface of the downhole logging tool;
disposing the downhole logging tool in a wellbore having fluids therein;
obtaining NMR measurements on fluids proximate to the one or more surface NMR microcoils; and
inferring a characteristic of the proximate fluids based on the NMR measurements.

14. The method of claim 13, wherein:
the one or more surface NMR microcoils each have a central axis and are disposed circumferentially around the outer surface of the downhole logging tool with the surface NMR microcoil central axis, for any particular surface NMR microcoil, being substantially perpendicular to the LWD tool longitudinal axis, substantially parallel to the longitudinal axis of the downhole logging tool, or oriented at some angle in between substantially perpendicular and substantially parallel to the longitudinal axis of the downhole logging tool.

15. The method of claim 13, wherein the inferring a characteristic of the proximate fluids comprises providing similar information as SARA analysis at downhole pressure and temperature and in a repeatable manner.

16. The method of claim 13, wherein the NMR measurement system further comprises:
a central flow line having a longitudinal axis, the central flow line being in fluid communication with drilling fluid in an interior region of a drill pipe; and one or more additional surface NMR microcoils, wherein each of the one or more additional surface NMR microcoils has a central axis and is disposed circumferentially around the central flow line with the surface NMR microcoil central axis being substantially perpendicular to the central flow line longitudinal axis, substantially parallel to the central flow line longitudinal axis, or oriented at some angle in between substantially perpendicular and substantially parallel to the central flow line longitudinal axis; the method further comprising:
obtaining NMR measurements on the fluid within an interior region of the central flow line using the one or more additional surface NMR microcoils; and
inferring a characteristic of the drilling fluid based on the NMR measurements.

17. The method of claim 13, wherein the NMR measurement system further comprises:
a central flow line having a longitudinal axis, the central flow line being in fluid communication with drilling fluid in an interior region of a drill pipe; and a flow line NMR microcoil having a central axis, wherein the flow line NMR microcoil circumferentially encloses the central flow line and the flow line NMR microcoil central axis is substantially parallel to the central flow line longitudinal axis; the method further comprising:
obtaining NMR measurements on the fluid within an interior region of the central flow line using the flow line NMR microcoil; and
inferring a characteristic of the drilling fluid based on the NMR measurements.

18. The method of claim 13, wherein the NMR measurement system further comprises:
a bypass flow line having a longitudinal axis, the bypass flow line being in fluid communication with fluid in the wellbore annulus; and a bypass flow line NMR microcoil having a central axis, wherein the bypass flow line NMR microcoil circumferentially encloses the bypass flow line and the bypass flow line central axis is substantially parallel to the bypass flow line longitudinal axis; the method further comprising:
obtaining NMR measurements on the fluid within an interior region of the bypass flow line using the bypass flow line NMR microcoil; and
inferring a characteristic of the fluid in the wellbore annulus based on the NMR measurements.

19. The method of claim 13, wherein the NMR measurement system further comprises:
a bypass flow line having a longitudinal axis, the bypass flow line being in fluid communication with fluid in the wellbore annulus; and one or more additional surface NMR microcoils, wherein each of the one or more additional surface NMR microcoils has a central axis and is disposed circumferentially around the bypass flow line with the surface NMR microcoil central axis being substantially perpendicular to the bypass flow line longitudinal axis, substantially parallel to the bypass flow line longitudinal axis, or oriented at some angle in between substantially perpendicular and substantially parallel to the bypass flow line longitudinal axis; the method further comprising:
obtaining NMR measurements on the fluid within an interior region of the bypass flow line using the one or more additional NMR microcoils; and
inferring a characteristic of the fluid in the wellbore annulus based on the NMR measurements.

20. The method of claim 13, wherein the NMR measurement system further comprises:
a bypass flow line having a longitudinal axis, the bypass flow line being in fluid communication with drilling fluid in an interior region of a drill pipe; and a bypass flow line NMR microcoil having a central axis, wherein the bypass flow line NMR microcoil circumferentially encloses the bypass flow line and the bypass flow line central axis is substantially parallel to the bypass flow line longitudinal axis; the method further comprising:
obtaining NMR measurements on the fluid within an interior region of the bypass flow line using the bypass flow line NMR microcoil; and
inferring a characteristic of the drilling fluid based on the NMR measurements.

21. The method of claim 13, wherein the NMR measurement system further comprises:
a bypass flow line having a longitudinal axis, the bypass flow line being in fluid communication with drilling fluid in an interior region of a drill pipe; and one or more additional surface NMR microcoils, wherein each of the one or more additional surface NMR microcoils has a central axis and is disposed circumferentially around the bypass flow line with the surface NMR microcoil central axis being substantially perpendicular to the bypass flow line longitudinal axis, substantially parallel to the bypass flow line longitudinal axis, or oriented at some angle in between substantially perpendicular and substantially parallel to the bypass flow line longitudinal axis; the method further comprising:
obtaining NMR measurements on the fluid within an interior region of the bypass flow line using the one or more additional NMR microcoils; and
inferring a characteristic of the drilling fluid based on the NMR measurements.

22. The method of claim 13, wherein the NMR measurement system further comprises:
a bypass flow line having a longitudinal axis, the bypass flow line being selectively in fluid communication with fluid in the wellbore annulus or selectively in fluid communication with drilling fluid in an interior region of a drill pipe; and a bypass flow line NMR microcoil having a central axis, wherein the bypass flow line NMR microcoil circumferentially encloses the bypass flow line and the bypass flow line central axis is substantially parallel to the bypass flow line longitudinal axis; the method further comprising:
obtaining NMR measurements on the fluid within an interior region of the bypass flow line using the bypass flow line NMR microcoil; and
inferring a characteristic of the fluid in the interior region of the bypass flow line based on the NMR measurements.

23. The method of claim 13, wherein the NMR measurement system further comprises:
a bypass flow line having a longitudinal axis, the bypass flow line being selectively in fluid communication with fluid in the wellbore annulus or selectively in fluid communication with drilling fluid in an interior region of a drill pipe; and one or more additional surface NMR microcoils, wherein each of the one or more additional surface NMR microcoils has a central axis and is disposed circumferentially around the bypass flow line with the surface NMR microcoil central axis being substantially perpendicular to the bypass flow line longitudinal axis, substantially parallel to the bypass flow line longitudinal axis, or oriented at some angle in between substantially perpendicular and substantially parallel to the bypass flow line longitudinal axis; the method further comprising:
obtaining NMR measurements on the fluid within an interior region of the bypass flow line using the one or more additional NMR microcoils; and
inferring a characteristic of the fluid in the interior region of the bypass flow line based on the NMR measurements.

24. The method of claim 13, wherein the downhole logging tool comprises a logging-while-drilling (LWD) logging tool.

25. An apparatus for making NMR measurements downhole as substantially described herein.
